(19) United States
(12) Patent Application Publication
(10) Pub. No.: US 2013/0148272 A1
(43) Pub. Date: Jun. 13, 2013

(54) PORTABLE ELECTRONIC DEVICE

(71) Applicants: CHENG-KUEI LIN, TAIPEI CITY (TW); WEI-YUN CHEN, TAIPEI CITY (TW); CHING-FENG HSIEH, TAIPEI CITY (TW)

(72) Inventors: CHENG-KUEI LIN, TAIPEI CITY (TW); WEI-YUN CHEN, TAIPEI CITY (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/351,465

(22) Filed: Jan. 17, 2012

(30) Foreign Application Priority Data
Dec. 9, 2011 (TW) 100145571

(51) Int. Cl. H05K 5/00

(52) U.S. Cl. 361/679.01

(57) ABSTRACT

A portable electronic device includes a first display portion, a second display portion, and at least a replaceable casing. The second display portion is pivotally connected to the first display portion. The first display portion and the second display portion turn relative to each other. The replaceable casing is coupled to the first display portion and/or the second display portion. The portable electronic device with the at least a replaceable casing enables users to change the at least a replaceable casing that comes in different colors and styles to meet user needs.

### CROSS-REFERENCE TO RELATED APPLICATION

This non-provisional application claims priority under 35 U.S.C. § 119(a) on Patent Application No(s).100145571 filed in Taiwan, R.O.C. on Dec. 9, 2011, the entire contents of which are hereby incorporated by reference.

### FIELD OF TECHNOLOGY

The present invention relates to portable electronic devices, and more particularly, to a portable electronic device capable of changing a casing thereof independently.

### BACKGROUND

Technological advancement is accompanied by increasingly great demand for portable electronic devices. Functions and appearance of portable electronic devices are ever-changing to satisfy every taste, including the need for personalized design and uniqueness among emerging consumers—one of the current market trends.

A typical conventional portable electronic device is equipped with a casing and a screen which are fixed to each other. Hence, at the moment of its delivery, the conventional portable electronic device features an invariable appearance. Although the casings of the conventional portable electronic devices come in different colors and styles, users cannot change the casings according to user preference.

Likewise, users cannot change a scratched or damaged casing of the conventional portable electronic device on their own. To change the scratched or damaged casing, the users have to send the conventional portable electronic device in its entirety to the manufacturer for maintenance; however, doing so incurs costs and is time-consuming

Accordingly, it is imperative to devise a portable electronic device with a casing that can be changed by users as needed and independently so as to alter the appearance of the portable electronic device.

### SUMMARY

In view of the aforesaid drawbacks of the prior art, the inventor of the present invention conceives room for improvement in the prior art and thus conducted extensive researches and experiments according to the inventor's years of experience in the related industry, and finally developed a portable electronic device as disclosed in the present invention to enable users to change the casing of the portable electronic device as needed and independently so as to alter the appearance of the portable electronic device.

In order to achieve the above and other objectives, the present invention provides a portable electronic device comprising a first display portion; a second display portion pivotally connected to the first display portion, allowing the first display portion and the second display portion to turn relative to each other; and at least a replaceable casing coupled to at least one of the first display portion and the second display portion.

Regarding the portable electronic device, the first display portion has a first body and a first display unit, such that the first display unit and the replaceable casing can be disposed at the first body.

Regarding the portable electronic device, the second display portion has a second body and a second display unit, such that the second display unit and the replaceable casing are disposed on the second body.

Regarding the portable electronic device, the replaceable casing has a removable coupling unit, and the display portions have a removable coupling unit each, such that the replaceable casing and the first display portion can be coupled together, and the replaceable casing and the second display portion can be coupled together.

Regarding the portable electronic device, the replaceable casing has a positioning unit, and the display portions have a positioning unit each, such that the replaceable casing and the first display portion are positioned relative to each other, and the replaceable casing and the second display portion are positioned relative to each other.

Regarding the portable electronic device, the replaceable casing has a removable coupling unit, and the body has a removable coupling unit, such that the replaceable casing and the first body can be coupled together, and the replaceable casing and the second body can be coupled together.

Regarding the portable electronic device, the replaceable casing has a positioning unit, and the body has another positioning unit, such that the replaceable casing and the first body are positioned relative to each other, and the replaceable casing and the second body are positioned relative to each other.

Regarding the portable electronic device, the removable coupling units are flange and groove, resilient hook and coupling hole, or coupling hole and resilient hook.

Regarding the portable electronic device, the removable coupling units are magnetic body and magnet, magnet and magnetic body, N-pole magnet and S-pole magnet, or S-pole magnet and N-pole magnet.

Regarding the portable electronic device, the positioning units are either positioning post and positioning recess or positioning recess and positioning post.

Regarding the portable electronic device, the display portions each have a disassembly recess adjacent to the replaceable casing.

Accordingly, a portable electronic device of the present invention enables users to change a replaceable casing that comes in different colors and styles to meet user needs.

### BRIEF DESCRIPTION

Objectives, features, and advantages of the present invention are hereunder illustrated with specific embodiments in conjunction with the accompanying drawings, in which:

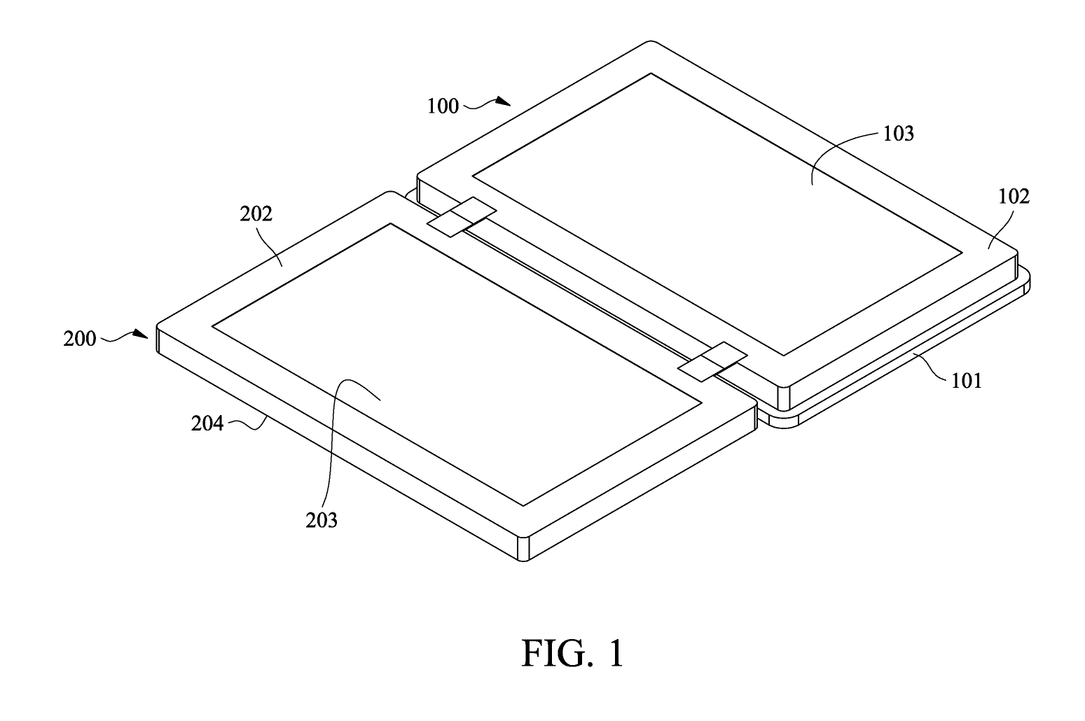

FIG. 1 is a schematic view of a portable electronic device according to a specific embodiment of the present invention;

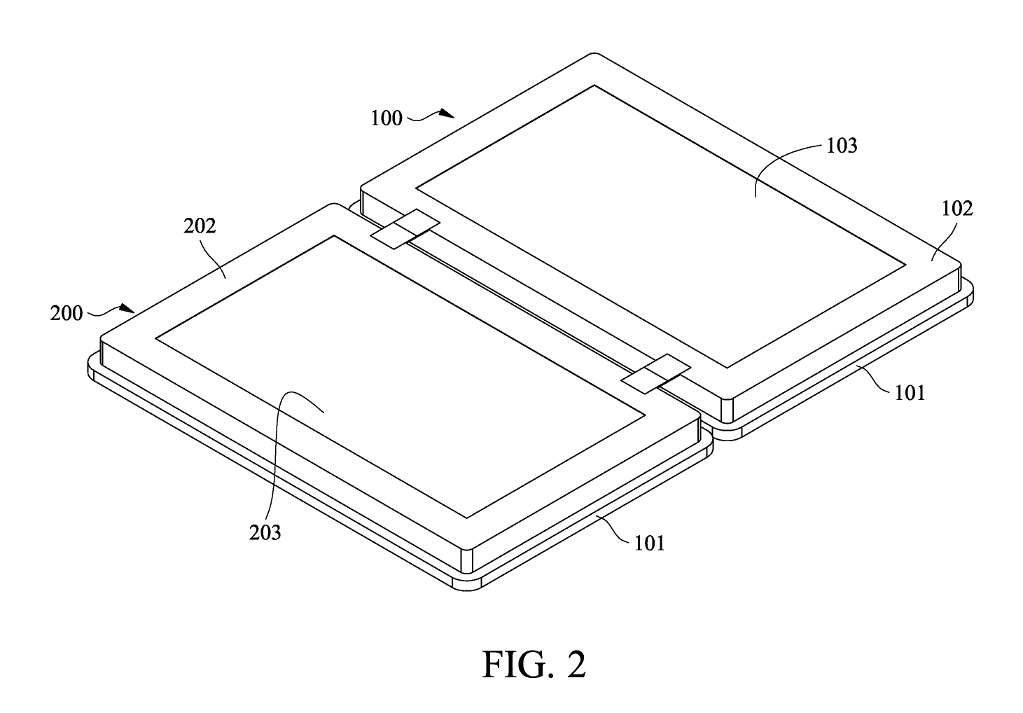

FIG. 2 is another schematic view of the portable electronic device according to a specific embodiment of the present invention;

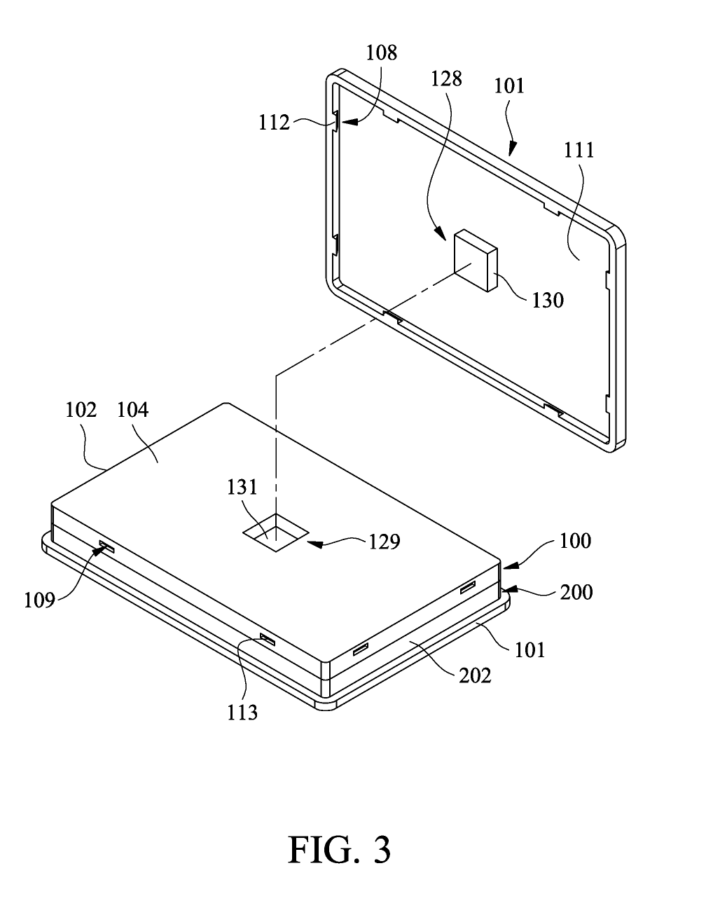

FIG. 3 is a schematic view of the portable electronic device with a replaceable casing and a display portion before the coupling thereof according to a specific embodiment of the present invention;

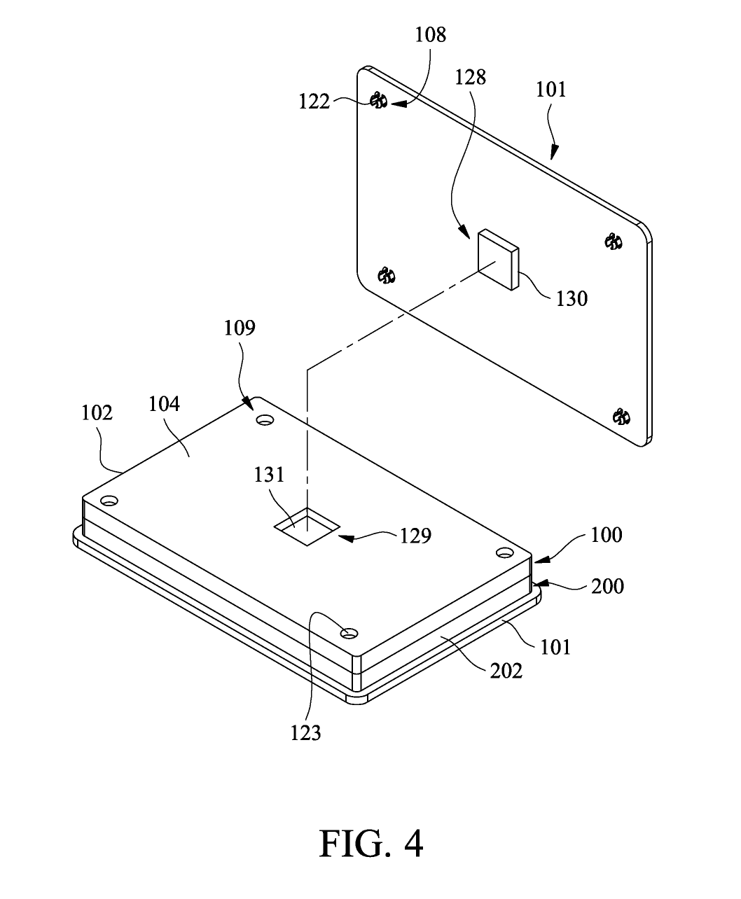

FIG. 4 is another schematic view of the portable electronic device with a replaceable casing and a display portion before the coupling thereof according to a specific embodiment of the present invention;

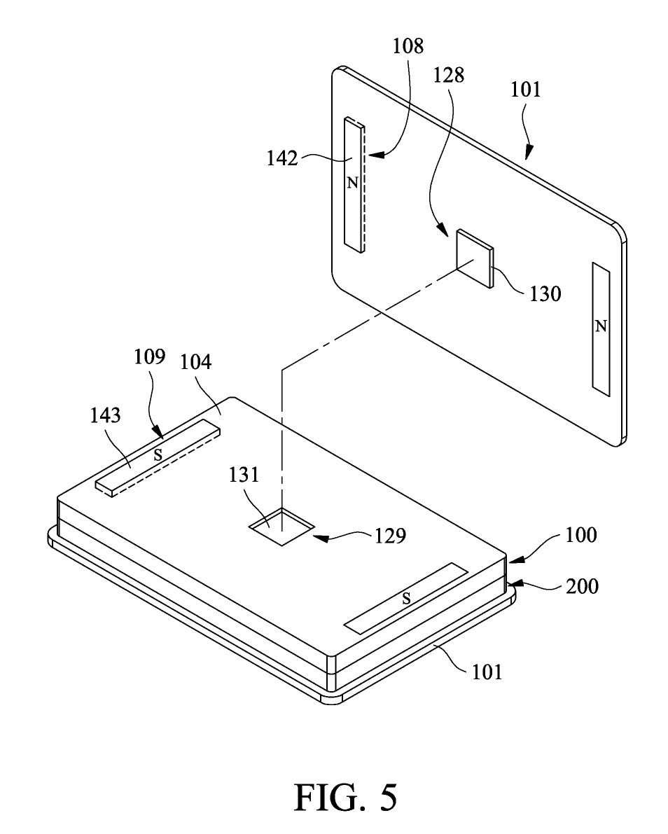

FIG. 5 is yet another schematic view of the portable electronic device with a replaceable casing and a display portion before the coupling thereof according to a specific embodiment of the present invention;

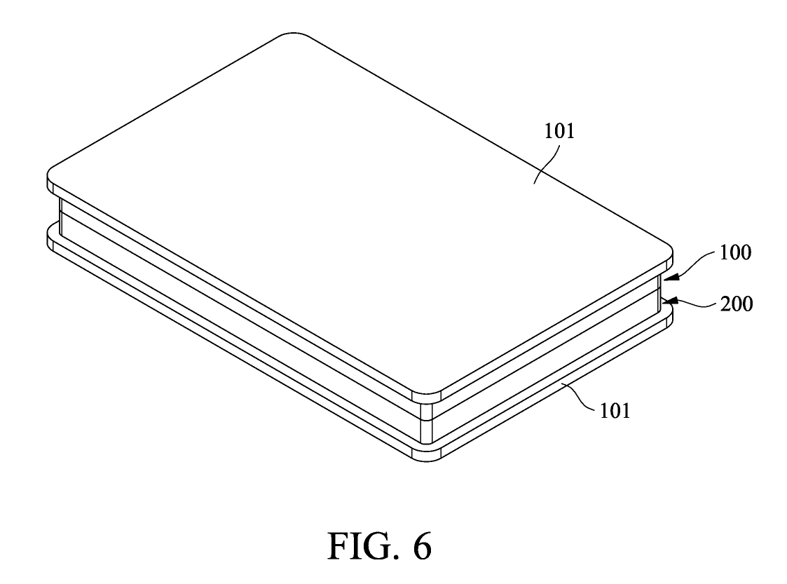

FIG. 6 is a schematic view of the portable electronic device with a replaceable casing and a display portion after the coupling thereof according to a specific embodiment of the present invention, showing that the replaceable casing extends outward on all sides of the display portion; and

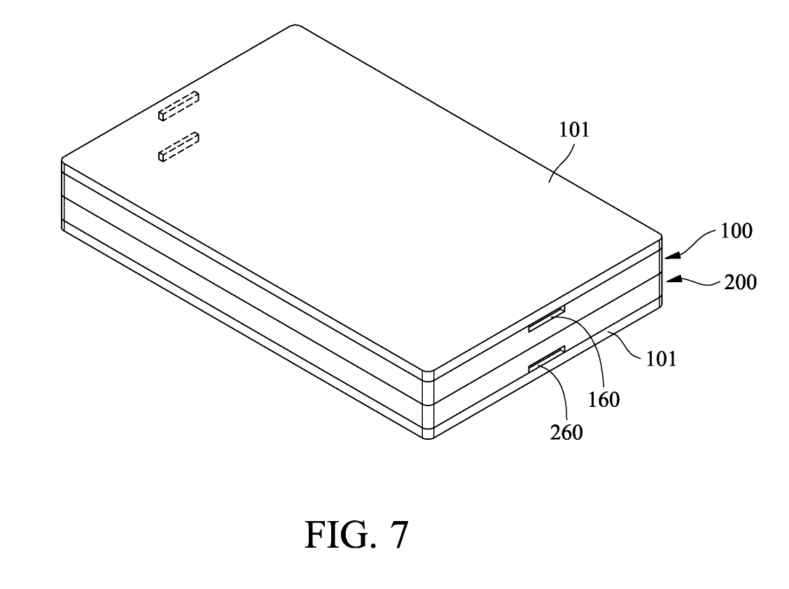

FIG. 7 is a schematic view of the portable electronic device with display portions having disassembly recesses according to a specific embodiment of the present invention.

### DETAILED DESCRIPTION

Referring to FIG. 1, there is shown a schematic view of a portable electronic device according to a specific embodiment of the present invention. As shown in the drawing, a portable electronic device of the present invention comprises a first display portion 100, a second display portion 200, and at least one replaceable casing 101. The second display portion 200 is pivotally connected to the first display portion 100. The first display portion 100 and the second display portion 200 can turn relative to each other to form a portable electronic device capable of opening and shutting. The replaceable casing 101 is coupled to at least one of the first display portion 100 and the second display portion 200.

Referring to FIG. 2, there is shown another schematic view of the portable electronic device according to a specific embodiment of the present invention. As shown in the drawing, the portable electronic device further comprises another replaceable casing 101 disposed at the second display portion 200.

In the above embodiment, the first display portion 100 has a first body 102 and a first display unit 103. The first display unit 103 and the replaceable casing 101 are disposed on an outer wall surface 104 of the first body 102. The second display portion 200 has a second body 202 and a second display unit 203. The second display unit 203 and the other replaceable casing 101 are disposed on an outer wall surface 204 of the second body 202. The first display unit 103 and the second display unit 203 are liquid crystal displays (LCD) or light-emitting diode (LED) displays. The first body 102 and the second body 202 accommodate electronic components, such as a hard disk drive (HDD), a central processing unit (CPU), or a circuit board (not shown).

Referring to FIG. 3 through FIG. 5, there are shown schematic views of the portable electronic device with the replaceable casing 101 and the first display portion 100 before the coupling thereof according to a specific embodiment of the present invention. As shown in the drawings, the replaceable casing 101 has a first removable coupling unit 108, whereas the first display portion 100 has a third removable coupling unit 109. The replaceable casing 101 and the first display portion 100 are coupled to each other by means of the first removable coupling unit 108 and the third removable coupling unit 109. The third removable coupling unit 109 can also be disposed on the first body 102. The replaceable casing 101 and the first body 102 are coupled to each other by means of the first removable coupling unit 108 and the third removable coupling unit 109.

Although FIG. 3 through FIG. 5 mainly illustrate the first removable coupling unit 108 and the third removable coupling unit 109 of the replaceable casing 101, the first display portion 100, and the first body 102, the drawings also apply to a second removable coupling unit and a fourth removable coupling unit of the other replaceable casing 101, the second display portion 200, and the second body 202. The second removable coupling unit and the fourth removable coupling unit of the second body 202 are equivalent to the first removable coupling unit 108 and the third removable coupling unit 109, respectively.

In the above embodiment, the replaceable casing 101 further comprises a first positioning unit 128, and the first display portion 100 further comprises a third positioning unit 129, such that the replaceable casing 101 and the first display portion 100 are engaged with each other by means of the first positioning unit 128 and the third positioning unit 129. Furthermore, it is feasible that the third positioning unit 129 is disposed on the first body 102, such that the replaceable casing 101 and the first body 102 are engaged with each other by means of the first positioning unit 128 and the third positioning unit 129. Once the replaceable casing 101 is mounted on the first display portion 100 or the first body 102 by a user, the replaceable casing 101 can be aligned with the third positioning unit 129 by means of the first positioning unit 128. Upon completion of the alignment, the first removable coupling unit 108 and the third removable coupling unit 109 correspond in position to each other. Then, after the user presses the replaceable casing 101 until it touches the first display portion 100 or the first body 102, the first removable coupling unit 108 and the third removable coupling unit 109 become coupled to each other. Hence, the first positioning unit 128 and the third positioning unit 129 together facilitate installation of the replaceable casing 101 on the first display portion 100 or the first body 102.

Although FIG. 3 through FIG. 5 mainly illustrate the first positioning unit 128 and the third positioning unit 129 of the replaceable casing 101, the first display portion 100, and the first body 102, the drawings also apply to a fourth positioning unit and a second positioning unit of the other replaceable casing 101, the second display portion 200, and the second body 202. The fourth positioning unit and the second positioning unit of the second body 202 are equivalent to the first positioning unit 128 and the third positioning unit 129, respectively.

Referring to FIG. 3, the replaceable casing 101 is provided on one side thereof with a recess portion 111, and the first removable coupling unit 108 is a flange 112 located at the periphery of the recess portion 111 of the replaceable casing 101. The third removable coupling unit 109 is a groove 113 corresponding in position to the flange 112, and is disposed on a lateral side (especially a corresponding side) of the first display portion 100 and thus corresponds in position to the flange 112. The recess portion 111 receives a portion of the first display portion 100. The flange 112 is engaged with and received in the groove 113, so as to mount the replaceable casing 101 on the outer wall surface 104 of the first display portion 100. To change the replaceable casing 101, the user follows the steps: exerting a force upon the replaceable casing 101 such that the replaceable casing 101 undergoes recoverable deformation slightly due to its intrinsic resilience, so as to disconnect the flange 112 from the groove 113 and thereby remove the replaceable casing 101; and mounting another said replaceable casing 101 on the outer wall surface 104 of the first display portion 100 in the aforesaid manner. Alternatively, the groove 113 is disposed on a lateral side of the first body 102, allowing the replaceable casing 101 to be changed in the aforesaid manner. FIG. 3, which depicts the flange 112 and the groove 113, is not supposed to be restrictive of the dimensions, such as the lengths, of the flange 112 and the groove 113; instead, the dimensions, such as the lengths, of the flange 112 and the groove 113 are subject to changes as needed.

Referring to FIG. 4, the first removable coupling unit 108 is provided in the form of four resilient hooks 122 at the four corners of one side of the replaceable casing 101, respectively, and the third removable coupling unit 109 is provided in the form of four coupling holes 123 corresponding in position to the four resilient hooks 122, respectively, as the four coupling holes 123 are located at the four corners of the outer wall surface 104 of the first display portion 100, respectively. The quantity and positions of the resilient hooks 122 and the coupling holes 123 are subject to changes as needed. The resilient hooks 122 are engageable with the coupling holes 123, such that the replaceable casing 101 can be mounted on the outer wall surface 104 of the first display portion 100. To change the replaceable casing 101, the user follows the steps: exerting a force upon the replaceable casing 101 such that the resilient hooks 122 undergoes recoverable deformation due to their intrinsic resilience, so as to disconnect the resilient hooks 122 from the coupling holes 123 and thereby remove the replaceable casing 101; and mounting another said replaceable casing 101 on the outer wall surface 104 of the first display portion 100 in the aforesaid manner. Alternatively, the coupling holes 123 can be disposed on the outer wall surface 104 of the first body 102, and the replaceable casing 101 can be changed in the aforesaid manner. Alternatively, the resilient hooks 122 are disposed on the outer wall surface 104 of the first body 102 or the first display portion 100, and the coupling holes 123 are disposed at the replaceable casing 101.

In the above embodiment, the end of each the resilient hooks 122 has a hook structure with two oblique sides, such that it is easy for users to dismount and mount the replaceable casing 101 by means of the resilient hooks 122.

Referring to FIG. 5, the first removable coupling unit 108 is provided in the form of two rectangular N-pole magnets 142 embedded in one side of the replaceable casing 101 and arranged in a manner that they are opposite and parallel to each other, whereas the third removable coupling unit 109 is provided in the form of two rectangular S-pole magnets 143 corresponding in position to the N-pole magnets 142, respectively. The two rectangular S-pole magnets 143 are embedded in the outer wall surface 104 of the first display portion 100 and arranged in a manner that they are opposite and parallel to each other. The shapes, quantity and positions of the N-pole magnets 142 and the S-pole magnets 143 are subject to changes as needed. The N-pole magnets 142 are attracted to the S-pole magnets 143 and vice versa, and thus the replaceable casing 101 can be fixed to the first display portion 100. With the N-pole magnets 142 and the S-pole magnets 143 being embedded in the replaceable casing 101 and the first display portion 100 respectively, and not protruding therefrom, there can be a seamless contact rather than a gap between the replaceable casing 101 and the outer wall surface 104 of the first display portion 100. To change the replaceable casing 101, the user exerts a force upon the replaceable casing 101 to separate the N-pole magnets 142 from the S-pole magnets 143 and thereby remove the replaceable casing 101, and then the user mounts another said replaceable casing 101 on the outer wall surface 104 of the first display portion 100. Furthermore, it is feasible to provide a S-pole magnet, a magnetic body, or a random magnet at the replaceable casing 101 and provide a N-pole magnet, a random magnet, or a magnetic body at the outer wall surface 104 of the first display portion 100. Furthermore, the magnet or the magnetic body can also be disposed at the outer wall surface 104 of the first body 102, and the replaceable casing 101 can be changed in the aforesaid manner.

Although FIG. 3 through FIG. 5 mainly illustrate the replaceable casing 101, the first display portion 100 and the first body 102, the drawings also apply to the other replaceable casing 101, the second display portion 200 and the second body 202.

Referring to FIG. 3 through FIG. 5, the first positioning unit 128 disposed at the replaceable casing 101 is a positioning post 130, whereas the third positioning unit 129 disposed at the first display portion 100 or the first body 102 is a positioning recess 131. Alternatively, the first positioning unit 128 is the positioning recess 131 when the third positioning unit 129 is the positioning post 130. As shown in the drawings, both the positioning post 130 and the positioning recess 131 are cubic, but the height of the positioning post 130 is greater than the depth of the recess portion 111 or the height of the resilient hooks 122; hence, once the replaceable casing 101 is mounted on the first display portion 100 or the first body 102, the positioning post 130 and the positioning recess 131 are engaged with each other to serve two functions: placing the replaceable casing 101 at a fixed position relative to the first display portion 100 or the first body 102; and fixing the orientation of the replaceable casing 101 relative to the first display portion 100 or the first body 102 to thereby prevent the replaceable casing 101 from rotating relative to the first display portion 100 or the first body 102. FIG. 3 through FIG. 5 are not intended to be restrictive of the positions of the positioning post 130 and the positioning recess 131, as the positions of the positioning post 130 and the positioning recess 131 are subject to changes as needed. Alternatively, both the positioning post 130 and the positioning recess 131 are cylindrical (not shown) but at least two said positioning posts (not shown) and at least two said positioning recesses (not shown) have to be provided in order to fix the orientation of the replaceable casing 101 relative to the first display portion 100 or the first body 102. After the positioning post 130 and the positioning recess 131 have been engaged with each other and thus the replaceable casing 101 has been fixed to the first display portion 100 or the first body 102, the first removable coupling unit 108 and the third removable coupling unit 109 correspond in position to each other; meanwhile, the first removable coupling unit 108 and the third removable coupling unit 109 can be coupled together by a press given by the user to the replaceable casing 101 in the direction from the replaceable casing 101 to the first display portion 100 or the first body 102. In conclusion, due to the first positioning unit 128 and the third positioning unit 129, the replaceable casing 101 can be mounted on the first display portion 100 or the first body 102 conveniently.

Although the aforesaid description is directed to the replaceable casing 101, the first display portion 100 and the first body 102, it applies to the other replaceable casing 101, the second display portion 200 and the second body 202 as well.

Referring to FIG. 6, there is shown a schematic view of the portable electronic device with the replaceable casing 101 and the first display portion 100 after the coupling thereof according to a specific embodiment of the present invention, showing that the replaceable casing 101 extends outward on all sides of the first display portion 100 (or the first body 102). The user can grip the extension portion of the replaceable casing 101, open and remove the replaceable casing 101 easily. Likewise, the other replaceable casing 101 extends outward on all sides of the second display portion 200 (or the second body 202). The user can grip the extension portion of the other replaceable casing 101, open and remove the other replaceable casing 101 easily.

Referring to FIG. 7, there is shown a schematic view of the portable electronic device with display portions having disassembly recesses according to a specific embodiment of the present invention. As shown in the drawing, the first display portion 100 (or the first body 102) has a first disassembly recess 160. The first disassembly recess 160 is adjacent to the replaceable casing 101 and is disposed on a lateral side of the first display portion 100 (or the first body 102). The user can exert a force upon the first disassembly recess 160 to lift and remove the replaceable casing 101 easily. Furthermore, the second display portion 200 (or the second body 202) has a second disassembly recess 260. The second disassembly recess 260 is adjacent to the other replaceable casing 101 and is disposed on a lateral side of the second display portion 200 (or the second body 202). The user can exert a force upon the second disassembly recess 260 to lift and remove the other replaceable casing 101 easily.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A portable electronic device, comprising:
a first display portion;
a second display portion pivotally connected to the first display portion, allowing the first display portion and the second display portion to turn relative to each other; and
at least a replaceable casing coupled to at least one of the first display portion and the second display portion.

2. The portable electronic device of claim 1, wherein the first display portion has a first body and a first display unit, such that the first display unit and the replaceable casing are disposed on the first body.

3. The portable electronic device of claim 1, wherein the second display portion has a second body and a second display unit, such that the second display unit and the replaceable casing are disposed on the second body.

4. The portable electronic device of claim 1, wherein the replaceable casing has a first removable coupling unit, and the first display portion has a third removable coupling unit, such that the replaceable casing and the first display portion are coupled together by the first removable coupling unit and the third removable coupling unit.

5. The portable electronic device of claim 4, wherein the replaceable casing has a first positioning unit, and the first display portion has a third positioning unit, such that the replaceable casing and the first display portion are positioned relative to each other by the first positioning unit and the third positioning unit.

6. The portable electronic device of claim 5, wherein the first positioning unit is a positioning post when the third positioning unit is a positioning recess, and alternatively, the first positioning unit is the positioning recess when the third positioning unit is the positioning post.

7. The portable electronic device of claim 4, wherein the first removable coupling unit is a flange, a resilient hook, or a coupling hole when the third removable coupling unit is a groove, a coupling hole, or a resilient hook, respectively.

8. The portable electronic device of claim 4, wherein the first removable coupling unit is a magnetic body, a magnet, a N-pole magnet, or a S-pole magnet when the third removable coupling unit is a magnet, a magnetic body, a S-pole magnet, or a N-pole magnet, respectively.

9. The portable electronic device of claim 1, wherein the replaceable casing has a second removable coupling unit, and the second display portion has a fourth removable coupling unit, such that the replaceable casing and the second display portion are coupled together by the second removable coupling unit and the fourth removable coupling unit.

10. The portable electronic device of claim 9, wherein the replaceable casing has a second positioning unit, and the second display portion has a fourth positioning unit, such that the replaceable casing and the second display portion are positioned relative to each other by the second positioning unit and the fourth positioning unit.

11. The portable electronic device of claim 10, wherein the second positioning unit is a positioning post when the fourth positioning unit is a positioning recess, and alternatively the second positioning unit is a positioning recess when the fourth positioning unit is a positioning post.

12. The portable electronic device of claim 9, wherein the second removable coupling unit is a flange, a resilient hook, or a coupling hole when the fourth removable coupling unit is a groove, a coupling hole, or a resilient hook, respectively.

13. The portable electronic device of claim 9, wherein the second removable coupling unit is a magnetic body, a magnet, a N-pole magnet, or a S-pole magnet when and the fourth removable coupling unit is a magnet, a magnetic body, a S-pole magnet, or a N-pole magnet, respectively.

14. The portable electronic device of claim 1, wherein the first display portion has a first disassembly recess adjacent to the replaceable casing.

15. The portable electronic device of claim 1, wherein the second display portion has a second disassembly recess adjacent to the replaceable casing.
